(19) United States
(12) Patent Application Publication
(10) Pub. No.: US 2021/0248891 A1
(43) Pub. Date: Aug. 12, 2021

(54) ASSEMBLY AND METHOD FOR INCREASING THE SAFETY OF A PERSON IN THE EVENT OF AN ELECTRICAL ACCIDENT

(71) Applicant: Adaptive Regelsysteme Gesellschaft M.B.H., Salzburg (AT)

(72) Inventor: Ulrich Klapper, Rankweil (AT)

(21) Appl. No.: 17/254,572

(22) PCT Filed: Jun. 19, 2019
(86) PCT No.: PCT/EP2019/066119

§ 371 Date: Dec. 21, 2020

(30) Foreign Application Priority Data
Jun. 21, 2018 (AT) A50512/2018

(51) Int. Cl. G08B 21/02; G05B 9/02; H04W 76/10; H04B 1/3827

(52) U.S. Cl. CPC G08B 21/02; H04B 1/385; H04W 76/10; G05B 9/02

(57) ABSTRACT

Various aspects of the present disclosure are directed to a system for increasing the protection of a person in the region of an electrical system against electric shocks when touching conducting or live parts of the electrical system. In some embodiments, the system includes a protective device to be worn by a person that detects an electrical body current, wherein at least one further person with another protective device or an external communication device is in the vicinity of the person having an electrical accident. The protective device including a communication unit, in response to the electrical accident having an electrical accident with an unacceptable body current detected by the protective device, a communication link between the communication unit of the protective device of the person having the accident and the other protective device of the further person.

The present invention relates to a system with increased safety and an associated method, for a person working on an electrical system in the event of an electrical accident, wherein the person wears a protective device for detecting an electrical body current flowing through the person and wherein at least one further person is located in the vicinity of the accident victim wearing a protective device or an external communication device.

Electrical systems for supply, distribution and transmission of electrical energy, such as an energy supply system in a building or for a machine park or an electrical high-voltage grid or portions thereof, require regular inspection, maintenance and servicing, which is carried out by appropriate persons, in some cases during operation. Special test devices are often used, which are connected to parts of the energy transmission system. Such test devices can generate high electrical voltages and/or currents for testing purposes. In this context, there is an inherent danger to such persons since, in the event of unintentional contact with conducting or live parts, an electric shock may cause death or at least the risk of sometimes considerable injuries. Generally, there are also persons in the vicinity of an electrical system who, in the event of incorrect operation or a fault in the electrical system, for example an insulation break, can also suffer an electric shock when touching a live component. It is therefore common in electrical systems, especially in an industrial environment, to provide an emergency stop in order to switch off the component if a person touches a conducting or live component. With such safety devices, the protection against electric shock due to unintentional contact of people working on conducting parts or live parts can be increased by other people present triggering the emergency stop in the event of a fault. However, this requires that at least one further person is in the vicinity of an electrical accident and has knowledge of the electrical accident, which is not always the case.

Methods and devices for a better protection of persons against unacceptable electrical body currents are therefore already known. DE 39 03 025 A1, for example, describes such a method and such a device, wherein an electrode connected to a control device is arranged on at least two extremities of the person, for example on the arms or legs. Via the electrodes, the control device detects a body current caused by a contact with an external electrical potential. If such a current flow is detected, the control device activates a shutdown device with which the further supply of current to the contact point is interrupted. The electrodes and the control device can be arranged on an item of clothing with a wireless connection between the control device and the switch-off device. DE 44 38 063 A1 describes a similar protective device. Such protective devices can increase the safety of persons working on conducting parts or live parts against electric shock due to unintentional contact.

It is therefore the object of the present invention to increase the safety of persons in the area of an electrical system against electric shock when touching conducting or live parts of the electrical system.

According to the invention, this object is achieved in that a communication unit is provided on the protective device of the person having the accident with the protective device of the person having the accident, at least in the case of an electrical accident with an unacceptable body current detected by the protective device, establishing a communication link between the communication unit of the protective device of the person having the accident and the protective device of the further person or between the communication unit of the protective device of the person having the accident and the external communication device of the other person and the protective device of the accident victim informs the at least one other person of the electrical accident via the communication link. It can thus be ensured that at least one further person in the vicinity of the person having the accident is informed of a possible electrical accident. This further person can then take efficient action to rescue the person having the accident or protect other people in the vicinity, for example by switching off or short-circuiting a circuit or by pushing the person having the accident away from the place of the accident. In the case of electric shocks, in particular, quick help can save lives, which is made possible by the present invention. At the same time, the protection of other people against possible electric shocks can be increased because they are immediately informed of a power failure in the vicinity.

Further advantageous embodiments and effects of the invention can be gathered from the dependent claims and the following description.

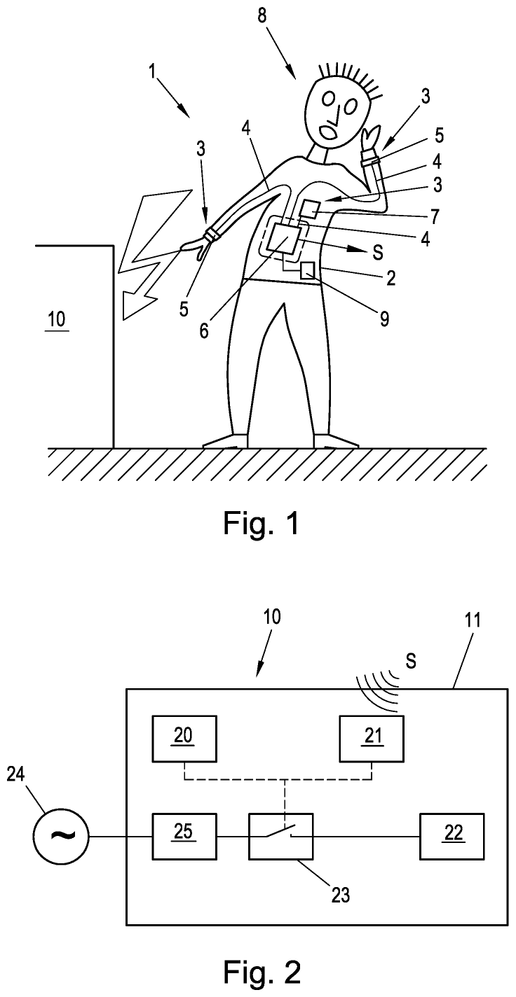

In the following, the present invention is described in greater detail with reference to FIGS. 1 to 8, which, by way of example, show schematic and non-limiting advantageous embodiments of the invention. In the drawings:

FIG. 1 shows a protective device used for the invention,

FIG. 2 shows the integration of an emergency signal input for receiving an emergency signal in a device,

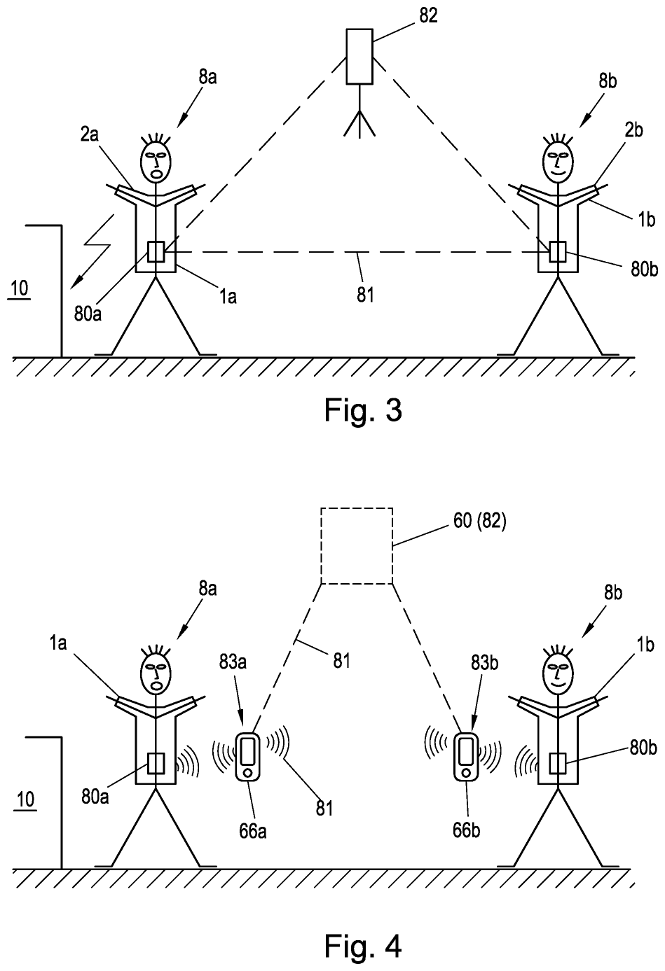

FIG. 3 shows an exemplary embodiment of the method, according to the invention, for notifying a further person in the vicinity of a person who had an electrical accident and who is wearing a protective device,

FIG. 4 shows the use of external communication devices for establishing a communication link,

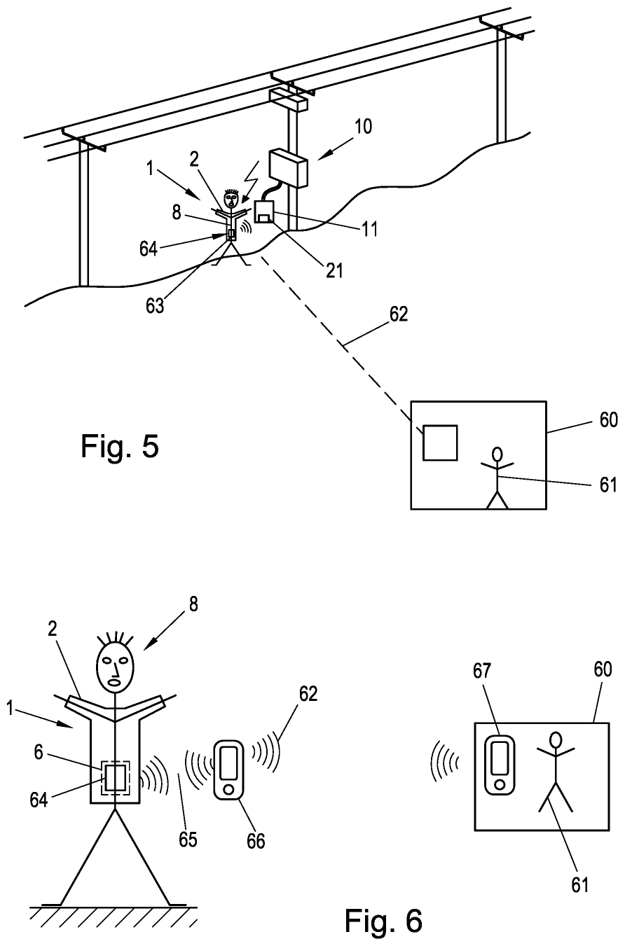

FIG. 5 shows the reporting of an electrical accident to a remote location,

FIG. 6 shows the alerting of the remote location via a mobile terminal,

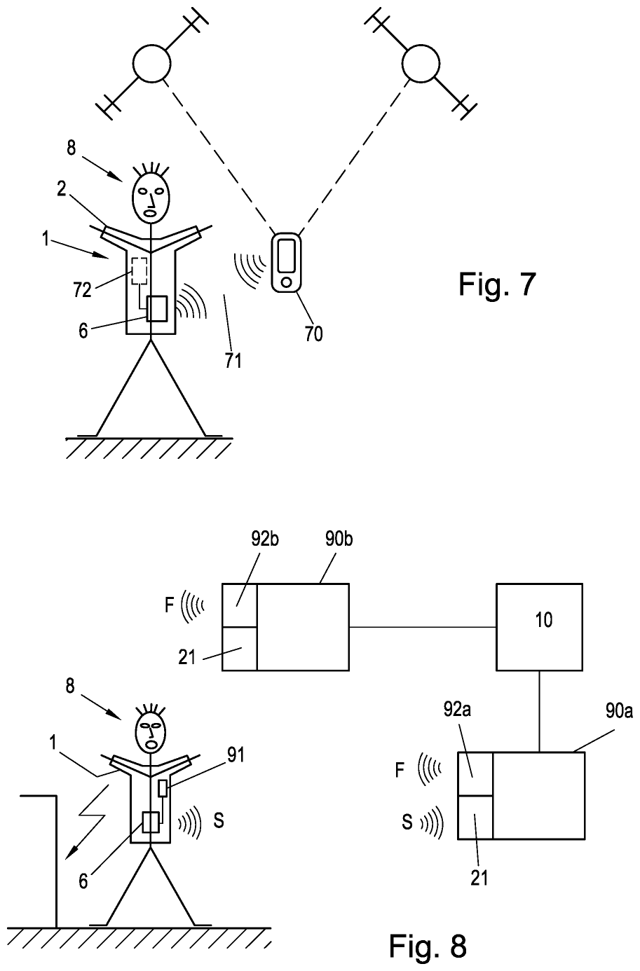

FIG. 7 shows the detection of the position of the person with a protective device and

FIG. 8 shows a system with a plurality of radio receivers for transmitting the emergency signal from a protective device.

The present invention uses a protective device 1, the basic function of which is known from prior art and which is explained in more detail with reference to FIG. 1 for a better understanding. The protective device 1, or at least parts thereof, is arranged on or integrated in an item of clothing 2, in this case a shirt. Of course, other items of clothing 2, for example trousers, a sweater, a T-shirt, a jacket, an overall, etc., can also be used. Even combinations of several items of clothing 2 are also possible, for example a combination of trousers and shirt, etc. At least one sensor 3 is arranged on the item of clothing 2 in order to detect an electrical body current flowing through the human body. In order to detect an electrical potential or an electrical current, electrodes 5 can, for example, be used as a sensor 3. The electrodes 5 are preferably arranged at exposed locations on the item of clothing 2, for example in the region of the extremities, i.e., for example on sleeves, trouser legs or hoods. A biometric sensor 7 can also be used as a sensor 3 in order to detect a biometric signal, for example the heart rate, the amplitude or the course of the heartbeat, the respiratory rate, the skin resistance, etc. By evaluating the biometric signal, in particular the heartbeat (frequency, amplitude and/or course), conclusions can also be drawn about a flowing electrical body current.

For this purpose, the sensor 3, or the sensors, can preferably be integrated in the item of clothing 2 but can also be applied separately, for example by means of a cuff, bracelet or belt. In a possible embodiment, a sensor 3 could be designed as an electrode 5 in the form of a known Rogowski coil (as in FIG. 1) in order to detect an electrical current flowing through an extremity or another part of the human body. For this purpose, the electrode 5 can be placed in a ring around an extremity, for example in a waistband of a sleeve or a trouser leg of the item of clothing 2. In order to detect an electrical potential, the electrode 5 must be in contact with the skin in an electrically conductive manner, whereas this would not be absolutely necessary in the case of a Rogowski coil, for example. A resistance measurement can also be carried out regularly or continuously between two electrodes 5 in order to check whether the item of clothing 2 is properly connected to the body of the person 8. In order to detect the heartbeat, a corresponding biometric sensor 7, for example a heart rate sensor, could be integrated in the item of clothing 2 in the region of the chest, or a corresponding chest strap could be applied.

A sensor 3 is connected via at least one signal line 4 to an evaluation unit 6 (for example, in the form of a computing unit, possibly also with corresponding software). The signals detected by the at least one sensor 3 are evaluated in the evaluation unit 6. An electrical potential detected with an electrode 5 as the sensor 3 or a detected flowing electric current can be evaluated, for example. An applied electrical voltage can be determined between two detected electrical potentials, for example with two sensors 3 designed as electrodes 5, and evaluated in the evaluation unit 6. The evaluation can likewise be carried out with suitable hardware or digitally, which requires an A/D conversion and the corresponding hardware and software. In the event a dangerous body current is detected, for example due to an abnormal heartbeat, a detected dangerous current flow or a dangerous potential difference (voltage) between two electrodes 5, which in turn indicates a current flow through the body, the evaluation unit 6 generates an emergency signal S which can be used to trigger a desired action. For this purpose, corresponding limit values for an acceptable body current, for example an acceptable potential difference or an acceptable current, can of course also be stored or specified in the evaluation unit 6, which can also be adjustable. Likewise, samples of a biometric signal that indicate a dangerous body current can also be stored in the evaluation unit 6.

Advantageously, different sensors 3 can be provided on the item of clothing 2 in order to increase the reliability of the detection of dangerous electrical body currents. For example, electrodes 5 could be provided on extremities and additionally a biometric sensor 7 for detecting the heartbeat, as shown in FIG. 1.

The safety of the protective device 1 can also be increased by providing redundancies. For example, more than one signal line 4 can be provided per sensor 3 so that possible cable breaks or contact errors do not have to lead to a failure of the safety function, or a cable break or contact error can even be recognized and possibly also indicated.

The evaluation unit 6 is preferably held or carried by the person 8 who wears the protective device 1. This evaluation unit could be arranged, for example, in a shoulder bag or a backpack but could also be pouched into a pocket of the item of clothing 2 or could also advantageously be integrated, wholly or partially, in the item of clothing 2, for example in the form of an intelligent item of clothing with integrated electronics.

The emergency signal S can in principle be emitted in a wired or wireless manner and can be received at the emergency signal input 21 in a wired or wireless manner.

The protective device 1 thus consists, for example, of an item of clothing 2 with at least one sensor 3 and an evaluation unit 6 which is connected to the at least one sensor 3 by at least one signal line 4 and which evaluates a signal detected by the sensor 3 in order to detect a dangerous electrical body current. The emergency signal S of the evaluation unit 6, or generally of the protective device 1, can be used in the electrical system 10 to trigger certain configured actions in order to increase the protection of a person 8 against electric shock. Such actions are, in particular, switching actions in order to disconnect the electrical system 10 or parts thereof from voltage.

This is explained by way of example with reference to FIG. 2, which shows a device 11 as an example of an electrical system 10 or part of an electrical system 10. A current and/or voltage generator 25 is provided in the device 11, which generates the required electrical currents and/or voltages at the current and voltage outputs 22 of the device 11. For this purpose, the device 11 is connected to a power supply 24, which can be external (for example, an electrical network or an external battery) or also internal (for example, in the case of a battery-operated device). In the device 11, a disconnection unit 23 is provided between the current and/or voltage generator 25 and the current and voltage outputs 22. The disconnection unit 23 could, however, also be provided upstream from the current and/or voltage generator 25 or at another suitable point in the device 11. The disconnection unit 23 can, of course, also have a multi-pole design, depending on the number of current and voltage outputs 22. The emergency stop switch 20, when actuated, activates the disconnection unit 23, for example a disconnection relay, in the device 11, which switches and/or short-circuits the current and voltage outputs 22 of the device 11 to be switched off. The emergency stop switch 20 can be manually operated by a person present in order to disconnect and/or short-circuit the outputs of the device 11 and/or the electrical system 10 and/or parts of an electrical system 10. An emergency signal input 21 is additionally provided on the electrical system 10, which, when an emergency signal S is received, in particular from the protective device 1, actuates the disconnection unit 23 of the emergency stop circuit. According to the invention, the emergency signal input 21 is consequently also connected to the disconnection unit 23 and activates the disconnection unit 23 when an emergency signal S is received via the emergency signal input 21. However, several serially connected disconnection units 23, each of which is controlled separately, could also, of course, be provided in the device 11 with the same effect, for example a disconnection unit for the emergency stop switch 20 and a disconnection unit 23 for the emergency signal input 21. The emergency signal input 21 does not necessarily have to be integrated into the device 11 but rather could also be designed as a separate unit that is connected to the device 11.

The electrical system 10, or a part thereof, can also, of course, be switched off in other ways. A switch could be activated, for example, to disconnect a circuit from the supply network. Likewise, a circuit could be short-circuited (for example, by connecting a phase to the neutral conductor) in order to trigger an automatic circuit breaker to disconnect the circuit from the network. A sufficiently high ground fault current could also be generated (for example, by connecting a phase to the ground with a resistor) to trip a ground-fault current circuit interrupter. In addition, there are, of course, also other options for switching off the electrical system 10 or parts thereof.

In the protective device 1, preferably on the item of clothing 2 or on an external unit that is in data connection with the protective device 1, at least one further sensor 9 can optionally be provided for detecting a further variable, with the further variable detecting a further condition of the person 8 (in addition to a possible body current). The further sensor 9 can, for example, be an acceleration sensor in order to be able to determine a fall of the person 8. A position sensor as a further sensor 9 can be used to detect if the person 8 is lying down. The further sensor 9 can be designed to record an ECG (electrocardiogram) which, in connection with an electrical accident, can provide important information about the condition of the person 8 having the accident. The respiration of the person victim 8 having the accident can also be recorded by means of an acceleration sensor or movement sensor as a further sensor 9. Of course, several further sensors 9 can also be provided on the protective device 1 with any combinations of the above sensors 9 being conceivable.

Values acquired with the sensor 3, or the sensors 3, and/or values acquired with at least one further sensor 9 can also be stored in the protective device 1 in a memory unit, for example in evaluation unit 6. This makes it possible to read stored values at a later point in time or to transmit them to other locations.

If the protective device 1 detects a contact between the person 8 and a conducting or live part of an electrical system 10 as described above, which causes an unacceptable body current to flow through the person 8, an emergency signal S is triggered, for example wirelessly, for example via a radio link. The protective device 1 thus triggers a switching operation on the electrical system 10 via the emergency signal input 21, which is aimed at switching off at least the part that a person 8 is touching.

In many situations, the protective device 1 can successfully actuate an emergency stop or initiate another switching action via an emergency signal input 21 and thus switch the electrical system 10 or at least parts of it in a currentless and voltage-free manner. When the protective device 1 is activated, an electric shock, however, has already occurred in these situations.

In many cases, several people will be in the area where the work is performed to carry out work on conducting parts of an electrical system 10. Typical examples are an accident with an electric vehicle or generally an electricity accident on which several firefighters or rescue workers are working, or work on power lines hanging down or overturned utility poles after a storm. In such situations, however, it can happen that an electrical accident involving a person 8 is not noticed by other people in the vicinity, even in the immediate vicinity. This can also put other people at risk, for example, because they touch the person 8 who has become part of the circuit or because they also touch the live part. Apart from this, an efficient action to rescue the accident victim 8 or to protect other people in the vicinity, for example by switching off or short-circuiting the electrical circuit or also by pushing the accident victim 8 away, is only possible if at least one further person in the vicinity becomes aware of the electrical accident. In such cases, a protective device 1 according to the invention can advantageously be used, as is described by way of example with reference to FIG. 3.

It is assumed that a plurality of people 8a, 8b, each with a protective device 1a, 1b, are in the vicinity of a live component of an electrical system 10, and that there is a communication link between the protective devices 1a, 1b. For this purpose, each protective device 1a, 1b can be provided with a communication unit 80a, 80b in order to be able to set up a communication link 81, for example a Bluetooth link. A communication unit 80a, 80b can be integrated in the item of clothing 2, for example again as part of intelligent clothing, but can also be provided as a separate component (hardware) in the protective device 1a, 1b. The communication link 81 can be set up permanently or set up also on an event-related basis. If a protective device 1a of a person 8a detects an unacceptable body current through the person 8a because this person 8a becomes part of a circuit, for example, the communication unit 80a of the protective device la worn by the person 8a informs the at least one further person 8b in the vicinity via the communication link 81 and the communication unit 80b of the protective device 1b worn by the further person 8b. The specific type of notification or data transmission does not matter here; it is only important that the further person 8b is alerted by the protective device 1a of the person 8a having the accident and is thus able to take an appropriate action to help the person 8a having the accident. This increases the safety the person 8a having the accident since help can be provided more quickly in the event of an electrical accident. Above all, the quick and targeted help can be decisive for the person 8a having the accident in the event of an electrical accident.

For this purpose, a corresponding signaling unit, for example an acoustic, visual or palpable alarm, can also be provided on a protective device 1a, 1b. If a protective device 1a, 1b is additionally provided with a unique identifier, it is possible to also indicate which protective device 1a is affected in order to be able to locate the person 8a involved in the accident more easily. However, a visual or acoustic signaling could also be started on the protective device 1a of the accident victim 8a in order to allow other persons 8b to quickly recognize which person 8a in the vicinity had an accident. The help for a person 8a having the accident can thus be considerably accelerated.

The communication units 80a, 80b of the two protective devices 1a, 1b do not have to communicate with one another directly. It would be conceivable, for example, for a communication center 82 to be set up in the work area with which the individual protective devices 1a, 1b are connected via their communication units 80a, 80b, as indicated in FIG. 3. In that case, the communication link 81 is established via the communication center 82. In that case, the communication center 82 ensures that an alarm is transmitted from one protective device 1a to all other known protective devices 1b. It can be provided that the protective devices 1 in the vicinity of the central communication unit 82 (within the reception and transmission area) log into the central communication unit 82 so that the central communication unit is aware of all the protective devices 1 present in the vicinity. Alternatively, the communication center 82 could also simply send an alarm (for example in the form of a broadcast message) which can be received by all protective devices 1 located in the reception area.

It is also conceivable that the communication units 80a of the protective device la of the person 8a having the accident connects to an external communication device 83a of the person 8a, for example a mobile terminal 66a (for example, via Bluetooth), which then establishes the communication link 81 to the further person 8b, as shown in FIG. 4. In this case, a communication link 81 is established to an external communication device 83b of the further person 8b, for example a mobile terminal 66b of the person 8b in order to alert the further person 8b. In addition, the external communication device 83b of the further person 8b could also be connected to a communication unit 80b of the protective device 1b of the further person 8b (for example, via Bluetooth), which in turn can optionally also trigger a signaling on the protective device 1b.

It could also be provided that the protective device 1b of the notified person 8b transmits an emergency signal S in the event of an alarm itself, which can then in turn be used for a switching operation in the electrical system 10.

Instead of an established communication center 82 in the vicinity of the persons 8a, 8b, the communication link 81 described could also take place via a remote point 60 as a communication center 82, as indicated in FIG. 4. This is of particular interest when the external communication devices 83a, 83b used are mobile terminals 66a, 66b which allow for a communication link 81 over a long distance.

The alerting of a further person 8b with a protective device 1b, which is in communication link 81 with the protective device la of the person 8a having the accident, is independent of whether an emergency signal S is output by the protective device la of the person 8a having the accident or whether, in the event the emergency signal S is output, a switching action is triggered that switches off the electrical system 10 or a part thereof. The safety of the person 8a having the accident is increased by the fact alone that at least one further person 8b in the vicinity is informed of an electrical accident, and this further person 8b then takes an efficient action to rescue the person 8a having the accident or to protect other people in the vicinity, for example by switching off or short-circuiting an electric circuit or by pushing the person 8a having the accident away. This also applies in the event that the protective device 1a outputs an emergency signal S that is intended to trigger a switching operation, but the switching operation remains unsuccessful for whatever reason. In this case too, alerting a further person 8b in the vicinity is an important step in increasing safety.

In order to increase the safety for the accident victim 8a even further, it can be provided that a protective device 1 establishes a radio link 62 (indicated by the dashed line) with a transmitter unit 64, such as a mobile radio transmitter 63, to a configured remote location 60 so that help for the person 8 having the accident is initiated or coordinated, preferably by a further person 61 at the remote location 60, as shown in FIG. 5. After both protective devices 1a, 1b have gained knowledge of the electrical accident, it is irrelevant which of the protective devices 1a, 1b involved sets up the radio link 62, which is why no further distinction is made in this regard. However, the remote location 60 is preferably notified by the protective device 1 of the person 8 having the accident. “Remote” means in this context that this further person 61 is at least so far away from the person 8 having the accident that this further person 61 can neither visually nor acoustically directly determine the condition of the accident victim. The further person 61 can, for example, be in an emergency center, which can be in a completely different location. Such a remote location 60 can also function as a communication center 82 as described above. The protective device 1 can establish the radio link 62 directly via the transmitter unit 64, for example by means of a mobile radio transmitter 63 which is integrated in the item of clothing 2, for example again as part of intelligent clothing. Alternatively, the protective device 1 can also establish the radio link 62 indirectly, for example, in that the protective device 1 connects, via the transmitter unit 64 and a suitable data connection 65, for example Bluetooth, to a mobile terminal 66, for example a smartphone (e.g., using Bluetooth), of the person 8, which then sets up the radio link 62 to the remote location 60, as shown in FIG. A specific message can be sent via the radio link 62, for example a text message (SMS), a data transmission (for example, by e-mail) or a call can be made. The further person 61 in the remote location 60 can also carry a mobile terminal 67 with him, which can be connected to the radio link 62 if necessary, for example via a mobile radio network. It is obvious that the remote location 60 (e.g., the emergency center) does not have to be stationary, in particular, if the further person 61 also uses a mobile terminal 67 to be contacted.

The transmitting unit 64, for example in the form of a mobile radio transmitter 63, is preferably integrated in the evaluation unit 6 or also in the item of clothing 2 itself (for example, in the form of intelligent clothing). The transmitting unit 64 can be controlled by the evaluation unit 6 of the protective device 1.

The further person 61 can then coordinate help for the person 8 having the accident. An emergency center may, for example, be aware of the location of persons 8 who work on electrical systems 10 that are live or under voltage. For example, maintenance work is planned on an energy supply network as an electrical system 10 (as in FIG. 3), and it is known when and where this will be carried out. The protective device 1 can be assigned to a specific person 8 and can also have a unique identifier (for example, a mobile phone number). This way, an emergency call (also as a text message or an e-mail) coming into the emergency center from a protective device 1 can be assigned to a location and/or a person 8 so that the further person 61 can be specifically coordinated help by an emergency helper.

The protective device 1 can also be equipped with a positioning unit 72. For this purpose, for example, the positioning unit 72 such as a GPS (Global Positioning System) sensor can be arranged on the item of clothing 2 (as indicated by dashed lines in FIG. 7) or integrated in the item of clothing, for example intelligent clothing with integrated electronics. Other satellite navigation systems such as GALILEO can also be used, of course. However, there are naturally other ways of determining the position of a person 8 by means of a positioning unit 72. A conclusion about the current position could be drawn, for example, from the availability of WLAN (Wireless LAN) networks. A position could also be determined via a mobile radio network, for example, by means of GSM positioning.

The protective device 1 can, however, also be connected to an external unit 71, which can carry out a position determination, as a positioning unit 72, as shown, for example, in FIG. 7. Today's mobile telephones or smart phones generally have a positioning system integrated in them so that a mobile terminal 66 can be used particularly advantageously as an external unit 71 for this purpose (as seen in FIG. 5). The external unit 71 can be a GPS receiver as well. The protective device 1 can thus be connected to the external unit 71 via a suitable data link 65, for example Bluetooth, in order to receive the current position of the person 8 from the external unit 71. To establish the link, a transmitting unit 64 could again be provided in the protective device 1, for example. The current position can be stored in the protective device 1, preferably in the evaluation unit 6 of the protective device 1, preferably with further details about an electrical accident such as the date, time, duration of the body current or the level of the current flow, in order to allow for a later evaluation. The current position is understood to refer both to geographic coordinates and a specific location. Since many external units 71 often also have a positioning function, the location can also be used directly as the current position.

Of course, the current position or the current location can also be transmitted to the remote location 60 (as in FIG. 5 or 6) in order to assist with the coordination of assistance for the person 8 having the accident. The current position or the current location could also be transmitted to the remote location 60 at certain time intervals in order to always know a current position or a current location of the person 8.

It is obvious that when a remote location 60 is notified by the protective device 1 in the event of an electrical accident, additional information, for example data from further sensors 9 on the protective device 1, can also be transmitted about the condition of the person 8, for example the physical position of the person 8 (fall, person is lying down), pulse, ECG, respiration. Such additional information can be important for coordinating the help and rescue operations.

The remote location 60 can, of course, also be automated to the extent that, in the event of an incoming message of an electrical accident of a person 8, certain actions are automatically taken, for example the notification of an ambulance service or helper, possibly also with the specific position or location of person 8, possibly also with other existing data. In this case, the further person 61 would not be absolutely necessary.

To this end, the remote location 60 could also determine the location of one or more helper in the vicinity of the person 8 having the accident and specifically inform him about the electrical accident. The helper who is locally closest to the person 8 having the accident is preferably determined. For this purpose, the helper can be equipped with a communication unit, for example a mobile phone or smart phone, which is contacted by the remote location 60 or by the further person 61 at the remote location 60 with a corresponding message. The message could be a text message, email, or the like, or a phone call.

A helper in the vicinity of the person having the accident could be determined in that the locations of all possible helpers are known at the remote location 60. The current location could be continuously transmitted to the remote location 60, for example, via the communication units of the helpers at predetermined intervals. However, a proximity could also be determined in such a way that it is determined whether a communication unit of the person 8 having the accident, for example a mobile terminal 66, can exchange messages with a communication unit of a helper, for example via Bluetooth, or whether both can receive the same WLAN network. This could also be continuously communicated to the remote location 60 by the respective communication unit so that the remote location 60 always has a current status.

Situations are conceivable in which a switching operation is carried out on the electrical system 10 by the emergency signal S, but this does not lead to the desired success, i.e., the absence of voltage on the part contacted. This can happen, for example, if an emergency circuit is interrupted but another electric circuit is available that is not connected to the emergency stop. Therefore, it is possible to monitor in the device 11, which receives the emergency signal S via the emergency signal input 21 and triggers a switching action, or in the electrical system 10, whether the switching action leads to the desired success within a predetermined period of time, for example 100 ms, namely the determination of the absence of voltage if the emergency signal S is no longer received by the protective device 1 after the switching operation. If the absence of voltage cannot be determined in the specified time period, a further switching action can be triggered in the electrical system 10, via the emergency signal input 21, for example, in order to switch off at least one further circuit. It is often the case, for example, that only certain sockets or power supplies are connected to an emergency circuit while other electrical parts are in a different circuit. In this way, the emergency circuit could first be disconnected as described, and in a second step, if the first step was unsuccessful, a defined additional circuit could be disconnected. Of course, different hierarchies of circuits can be defined, which are switched off one after the other. An emergency circuit could be switched off first, for example, then an adjacent emergency circuit or a circuit for normal sockets, then a circuit for the IT infrastructure in a certain part of a building, then the whole building and finally the power supply for a server room.

The protective device 1 of the person 8 having the accident, or a communication unit 80 of the protective device 1 or an external device 71 coupled to the protective device, for example a mobile phone that the person 8 is carrying, can also make further persons in the surrounding area, who may not be trained or have any special equipment, aware of the danger and the help that is needed. An acoustic warning such as “Warning—electrical accident—this person is under voltage. Do not touch this person. Interrupt the circuit or remove the person from the circuit” or “Warning—electrical accident—this person has suffered an electric shock. Touchable parts under voltage are nearby” would be conceivable, for example.

In the case of a radio link for transmitting the output signal S from the protective device 1 to a radio receiver 90 of the electrical system 10, it is, of course, possible to check, either continuously or at least at the beginning of the work, whether a radio link exists at all. If not, a corresponding alarm can be issued by the protective device 1, for example acoustically, visually or palpably. The same naturally applies if a low state of charge of an energy supply for the protective device 1 is detected in the protective device 1.

In certain applications, in particular in buildings, the radio link between the protective device 1 and the radio receiver for receiving the emergency signal can be interrupted easily and without noticing, in particular when the person 8 wearing the protective device 1 is moving. This can lead to false activations if a missing radio signal in the radio receiver triggers a switching action. In the worst case, the protective device 1 no longer provides protection for the person 8 carrying said device with this circumstance going unnoticed.

The electrical system 10 could also be configured differently depending on how dangerous the application is so that an interruption of the radio link forces a switch-off if the application is very dangerous but does not do so if the application is less dangerous.

Apart from this, at least two radio receivers 90a, 90b, each with an emergency signal input 21 for receiving an emergency signal S from the protective device 1, can be spatially distributed in the work area of the person 8, as shown in FIG. 8. A radio receiver 90a, 90b can be used with the electrical system 10 or the device 11 of the electrical system 10, as described above, to detect an emergency signal S from the protective device 1 and to trigger an action, in particular a switching action. In this case, the emergency signal input 21 would be arranged externally from the electrical system 10 or the device 11, and the electrical system 10 or the device 11 would be connected to the external emergency signal input 21 on the radio receiver 90a, 90b. The protective device 1 is in bidirectional radio communication with the radio receiver 90a, 90b. This means that a signal receiver 91 must be provided on the protective device 1 in order to be able to receive a radio signal F which is transmitted by a transmitter 92a, 92b in the radio receiver 90a, 90b. The signal receiver 91 is preferably arranged on the item of clothing 2 or integrated into the item of clothing 2 and connected to the evaluation unit 6 or another computing unit in the protective device 1. The radio signal F from a radio receiver 90a, 90b is sent continuously or at least at regular intervals and is received by the signal receiver 91 of the protective device 1. The protective device 1 is thus able to evaluate the signal quality of the radio channel between the protective device 1 and a radio receiver 90a, 90b. The protective device 1 can thus decide over which of the available radio channels the emergency signal S is to be sent.

A plurality of such radio receivers 90a, 90b can be distributed in a building or a system, and the protective device 1 can select a radio receiver 90a, 90b, for example the radio channel with the best signal quality, in order to transmit the emergency signal S via said channel. This way, the person 8 who wears the protective device 1 can move through the building or the installation without losing the radio link.

For the invention, however, it is in principle unimportant where the decision which radio receiver 90a, 90b is used for communication purposes is made. The decision could be made in the signal receiver 91, in the radio receivers 90a, 90b, in the electrical system 10, the device 11 or elsewhere.

1. System with increased safety for a person (8a) working on an electrical system in the event of an electrical accident, the system comprising:
a protective device configured and arranged to be worn by the person for detecting an electrical current flowing through the person;
another protective device configured and arranged to be worn by at least one further person or an external communication device is in the vicinity of the person having the accident;
the protective device including a communication unit, and the protective device of the person having the accident, at least in the event of an electrical accident with an unacceptable body current detected with the protective device, is configured and arranged to establish a communication link between the communication unit of the protective device of the person having the accident and the protective device of the at least one further person, or between the communication unit of the protective device of the person having the accident and the external communication device of the further person; and
the protective device of the person having the accident is further configured and arranged to inform the at least one further person of the electrical accident via the communication link.

2. The system according to claim 0, further including another communication unit provided on the protective device of the further person and that the communication link is established between the two communication units.

3. The system according to claim 1, characterized in that the protective device of the person having the accident sets up the communication link via an external communication device of the person having the accident.

4. The system according to claim 1, characterized in that the communication link is established via a communication center.

5. The system according to claim 1, characterized in that a transmitting unit is arranged on the protective device which, in the event a body current is detected, establishes a radio link to a predetermined remote location to inform the remote location of the electrical accident.

6. The system according to claim 5, characterized in that the transmitting unit establishes a data connection with a mobile terminal of the person wearing the protective device and that the mobile terminal establishes the radio link to the remote location.

7. The system according to claim 5, characterized in that a further person receives the information about the electrical accident in the remote location and that the further person coordinates help for the person having the accident.

8. The system according to claim 1, characterized in that the protective device includes an item of clothing and an evaluation unit,
wherein the person wears the item of clothing and that the item of clothing is equipped with at least one sensor to detect the body current, and that the evaluation unit is communicatively coupled to the at least one sensor and evaluates a received signal from the at least one sensor indicative of the detected body current.

9. The system according to claim 1, characterized in that the protective device outputs an emergency signal in the event of a detected unacceptable body current.

10. The system according to claim 9, characterized in that an emergency signal input is provided on the electrical system, the electrical system receives the emergency signal input and switches the electrical system (10) or part of the electrical system off.

11. The system according to claim 9, characterized in that the protective device transmits the emergency signal via radio to the electrical system and issues an alarm in the event there is no radio link.

12. The system according to claim 11, characterized in that, in the case of several possible radio links, the radio channel which has the best signal quality for the transmission of the emergency signal is selectable.

13. The system according to claim 1, characterized in that the protective device comprises at least one further sensor which detects a further condition of the person wearing the protective device and/or a unit for determining the position or location of the person.

14. The system according to claim 13, characterized in that the protective device also transmits data from the at least one further sensor and/or the position or location of the person to a predetermined remote location.

15. The system according to claim 1, characterized in that a protective device emits an acoustic, visual or palpable signal in the event of an electrical accident.

16. Method to increase the safety for a person working on an electrical system in the event of an electrical accident, the method including the following steps:
the person wears a protective device for detecting an electrical current flowing through the person;
at least one further person with a protective device or an external communication device is in the vicinity of the person having the accident,
determining an unacceptable body current with the protective device of the person having the electrical accident,
in the event an acceptable body current is detected, establishing a communication link between a communication unit of the protective device of the person having the accident and the protective device of the at least one further person, or between a communication unit of the protective device of the person having the accident and the external communication device of the at least one further person, and
the protective device of the person having the accident informs the at least one further person of the electrical accident via the communication link.

17. The method according to claim 0, characterized in that the communication link is established between the communication unit on the protective device of the person having the accident and a communication unit on the protective device of the further person.

18. The method according to claim 0, characterized in that the protective device of the person having the accident establishes the communication link via an external communication device of the person having the accident.

19. The method according to claim 16, characterized in that the communication link is established via a communication center.

20. The method according to claim 16, wherein in the event of the electrical accident the protective device establishes a radio link via a transmitter unit to a predetermined remote location in order to inform the remote location of the electrical accident.

21. The method according to claim 20, characterized in that the transmitting unit establishes a data connection with a mobile terminal of the person wearing the protective device and that the mobile terminal establishes the radio link to the remote location.

22. The method according to claim 20, characterized in that a further person receives the information about the electrical accident in the remote location and that the further person coordinates help for the person having the accident.

23. The method according to claim 20, characterized in that the protective device also transmits data from at least one further sensor of the protective device of the person having the accident and/or the position or location of the person to the remote location.

24. The method according to claim 16, characterized in that a protective device issues an acoustic, visual or palpable signal in the event of an electrical accident.

25. The method according to claim 16, characterized in that the protective device of the person having the accident outputs an emergency signal in the event of a recognized unacceptable body current, which is received in the electrical system at an emergency signal input, and the electrical system or part of the electrical system is switched off in the event that the emergency signal is received.
